(19) United States
(12) Patent Application Publication
(10) Pub. No.: US 2006/0049412 A1
(43) Pub. Date: Mar. 9, 2006

(54) CMOS image sensor and method for fabricating the same

(76) Inventor: Dong-Heon Cho, Chungcheongbuk-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/072,674

(22) Filed: Mar. 3, 2005

(30) Foreign Application Priority Data
Sep. 9, 2004 (KR) 2004-72280

(51) Int. Cl. H01L 33/00; H01L 31/12

(52) U.S. Cl. 257/80; 257/82

(57) ABSTRACT

Disclosed are a complementary metal oxide semiconductor (CMOS) device and a method for fabricating the same. The CMOS image sensor includes: a photodetector; a microlens formed on the photodetector; an insulating passivation layer formed on the microlens to protect the microlens; and an oxide layer with a refraction index lower than that of the microlens formed between the microlens and the insulating passivation layer. The method for fabricating a CMOS image sensor includes the steps of: forming a photodetector on a substrate; forming a microlens on the photodetector; forming an oxide layer having a refraction index lower than the microlens on the microlens; and forming an insulating passivation layer for protecting the microlens on the oxide layer.

### FIELD OF THE INVENTION

The present invention relates to a complementary metal oxide semiconductor (CMOS) image sensor; and more particularly, to a CMOS image sensor including a microlens capable of efficiently collecting a light and an upper structure of the microlens.

### DESCRIPTION OF RELATED ARTS

In general, a complementary metal oxide semiconductor (CMOS) image sensor is a semiconductor device that converts an optical image to an electrical signal. A charge coupled device (CCD) and the CMOS image sensor are typical examples of the image sensors.

In the image sensor, the charge coupled device (CCD) is a semiconductor device that each of metal-oxide-silicon (MOS) capacitors are placed in close proximity and charge carriers are stored in and transferred to the capacitors. The CMOS image sensor is a semiconductor device adopting a switching method for sequentially detecting an output by making and using MOS transistors as many as the number of pixels based on CMOS technology using peripheral circuits such as control circuits and signal processing circuits.

FIG. 1 is a circuit diagram illustrating a unit pixel of a conventional CMOS image sensor.

FIG. 1 is a circuit diagram illustrating the unit pixel provided with one photodiode (PD) and four MOS transistors for the conventional CMOS image sensor. The unit pixel is formed with a photodiode (PD) 100 for generating photo-generated charges by receiving a light, a transfer transistor for transferring the photo-generated charges collected at the photodiode 100 to a floating diffusion region 102, a reset transistor 103 for setting electric potentials of the floating diffusion region and discharging charges, thereby resetting the floating diffusion region 102, a drive transistor 104 for serving a role of a source follower buffer amplifier by that a voltage of the floating diffusion region is transferred to a gate and a select transistor 105 for serving a role in addressing and switching. Outside of the unit pixel, a load transistor 106 is formed to read an output signal.

FIG. 2 is a cross-sectional view illustrating a unit pixel of a conventional CMOS image sensor.

If examining the unit pixel of the conventional image sensor with reference to FIG. 2, a plurality of inter-layer insulation layers 13, 14 and 15 are sequentially formed on a photodetector. 11 formed on a substrate 10. More specifically, the plurality of inter-layer insulation layers are classified as a first inter-layer insulation layer 13, a second inter-layer insulation layer 14 and a third inter-layer insulation layer 15. A first interconnection line 16 is placed between the first inter-layer insulation layer 13 and the second inter-layer insulation layer 14. A second interconnection line 17 is placed between the second inter-layer insulation layer 14 and the third inter-layer insulation layer 15. Herein, a reference numeral 12 denotes a device isolation layer.

Furthermore, there are a plurality of planarization layers 18 and 20 on top of the third inter-layer insulation layer 15. Herein, a first planarization layer is denoted with a reference numeral 18 and a second planarization layer is denoted with a reference numeral 20. A color filter 19 is formed between the first planarization layer 18 and the second planarization layer 20. Herein, a reference numeral 19A denotes an adjacent color filter.

A microlens 21 is formed on the second planarization layer 20 and a low temperature insulating passivation layer 22 is formed thereon.

The conventional image sensor forms the first interconnection line 16 and the second interconnection line 17 on an upper structure of the photodetector 11 and a passivation layer is formed thereon. Afterwards, a planarization process is performed before forming the color filter 19 and then, the color filter 19 is formed. Then, the planarization process is performed thereon 19 one more time.

Thereafter, the microlens 21 is formed and then, the low temperature insulating passivation layer 22 is deposited for protecting a photoresist layer that is a main component of the microlens from external contamination and preventing a metal etch damage particularly generated during a bump process.

However, when an incident light passes the microlens through the low temperature insulating passivation layer, a difference in a refraction index between two materials is not large. Thus, the light incident on edges of the microlens cannot be collected to the photodetector 11, thereby frequently generating a case that the light gets incident on the metal interconnection lines surrounding the pixel.

That is, the light passing the edges of the microlens is not collected to the photodetector 11. Instead, the light is transferred to the surrounding metal interconnection line or even to the pixels adjacent to the metal interconnection line. Accordingly, a cross talk between the pixels is generated, thereby decreasing photosensitivity while the light reaches the photodetector 11 that is a photo-detecting unit.

### SUMMARY OF THE INVENTION

It is, therefore, an object of the present invention to provide a complementary metal oxide semiconductor (CMOS) device capable of preventing a decrease in photosensitivity generated by a low temperature insulating passivation layer formed for protecting a microlens.

In accordance with one aspect of the present invention, there is provided a complementary metal oxide semiconductor (CMOS) image sensor, including: a photodetector; a microlens formed on the photodetector; an insulating passivation layer formed on the microlens to protect the microlens; and an oxide layer with a refraction index lower than that of the microlens formed between the microlens and the insulating passivation layer.

In accordance with another aspect of the present invention, there is provided a method for fabricating a CMOS image sensor, including the steps of: forming a photodetector on a substrate; forming a microlens on the photodetector; forming an oxide layer having a refraction index lower than the microlens on the microlens; and forming an insulating passivation layer for protecting the microlens on the oxide layer.

### BRIEF DESCRIPTION OF THE DRAWINGS

The above and other objects and features of the present invention will become better understood with respect to the following description of the preferred embodiment given in conjunction with the accompanying drawings, in which:

FIG. 1 is a circuit diagram illustrating a unit pixel of a conventional complementary metal oxide semiconductor (CMOS) device;

FIG. 2 is a cross-sectional view illustrating a conventional CMOS image sensor;

FIGS. 3A to 3E are cross-sectional views illustrating a unit pixel of a CMOS image sensor in accordance with the preferred embodiment of the present invention; and

FIGS. 4A to 4C are graphs comparing an experiment data used for a unit pixel of a CMOS image sensor fabricated as shown in FIGS. 3A to 3E with that used for a unit pixel of a conventional CMOS image sensor.

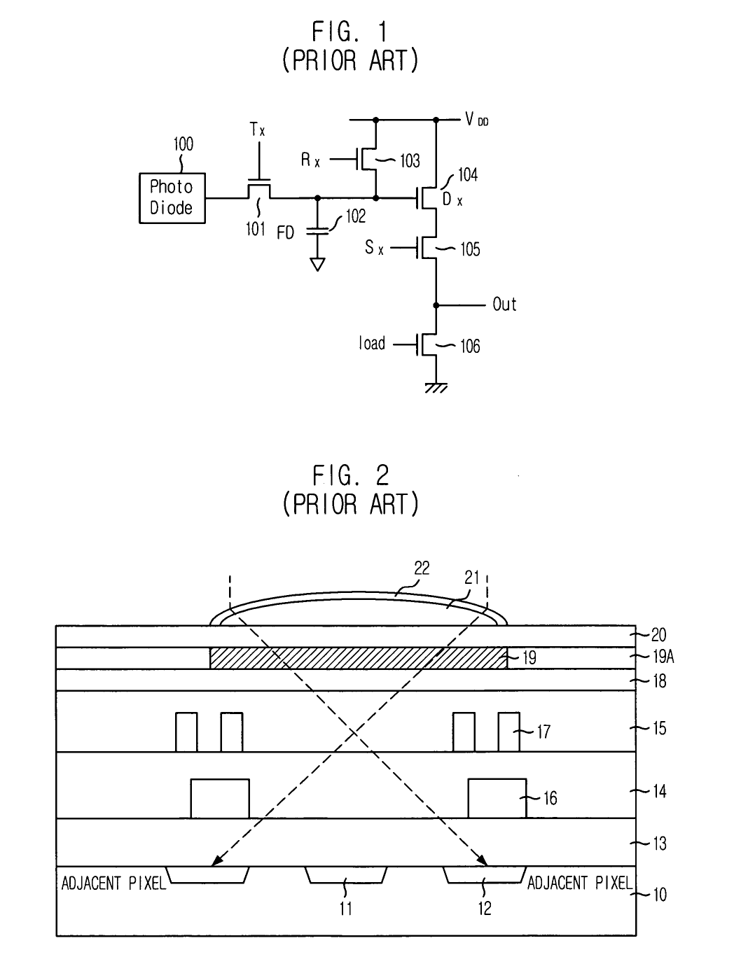

### DETAILED DESCRIPTION OF THE INVENTION

Hereinafter, detailed descriptions on preferred embodiments of the present invention will be provided with reference to the accompanying drawings.

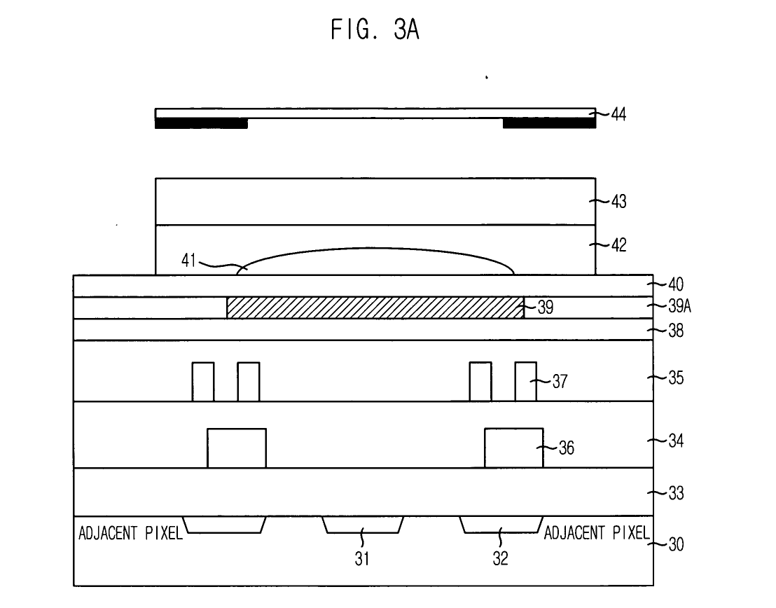

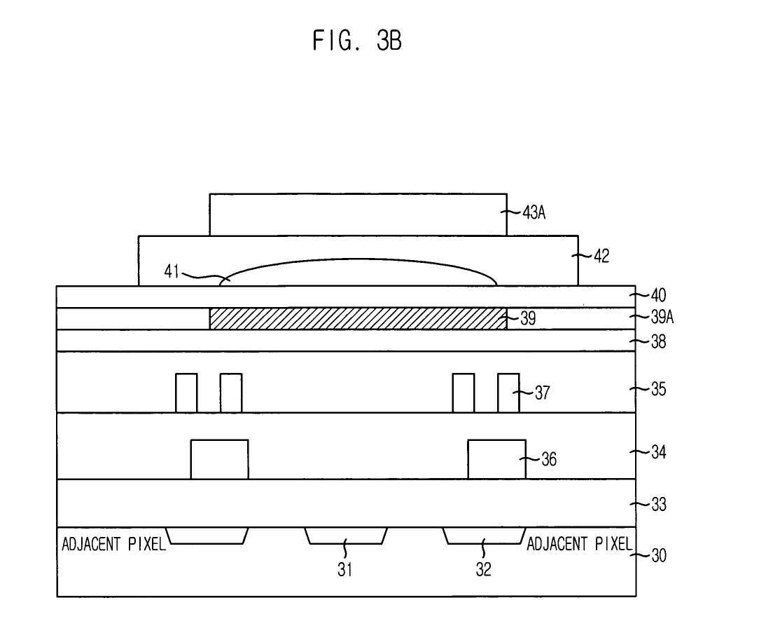

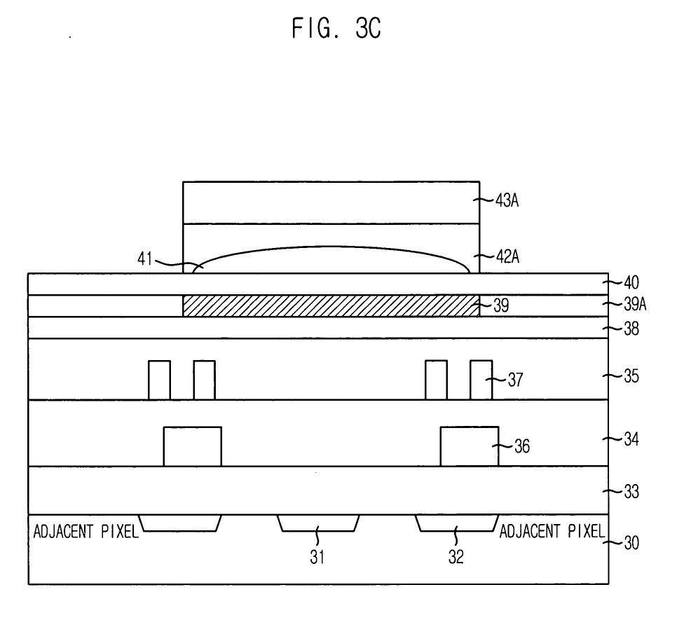

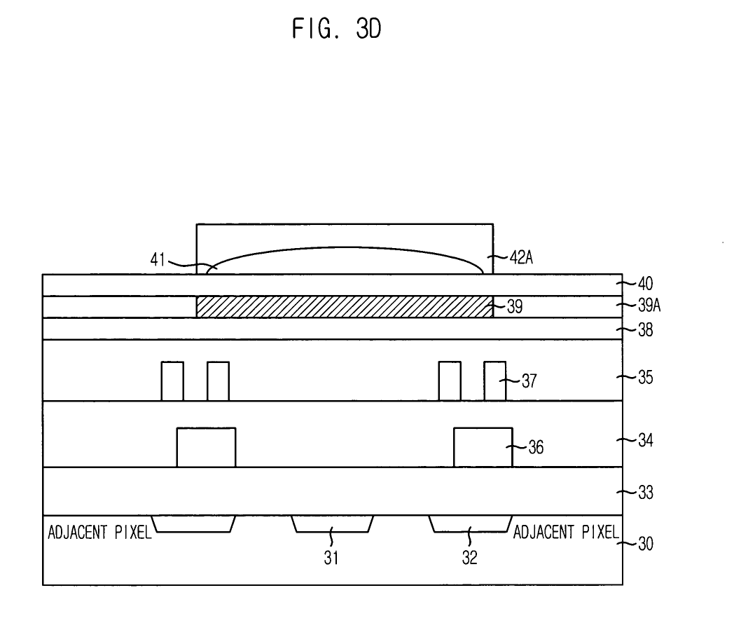

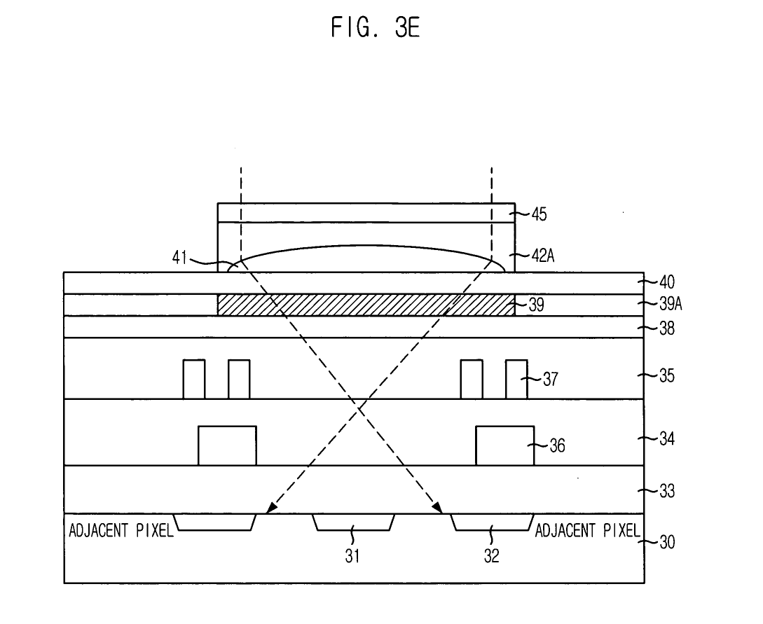

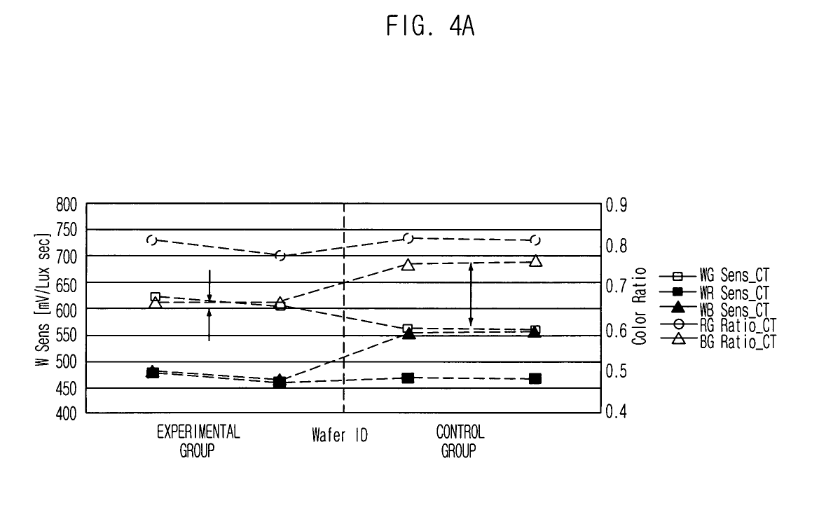

FIGS. 3A to 3E are cross-sectional views illustrating a unit pixel of a complementary metal oxide semiconductor (CMOS) image sensor in accordance with the preferred embodiment of the present invention.

As shown in FIG. 3A, the CMOS image sensor according to the present invention forms a photodetector 31 on a substrate 30.

Subsequently, a first inter-layer insulation layer 33, a second inter-layer insulation layer 34 and a third inter-layer insulation layer 35 are sequentially formed thereon. A first interconnection line 36 is formed between the first inter-layer insulation layer 33 and the second inter-layer insulation layer 34 and a second interconnection line 37 is formed between the second inter-layer insulation layer 34 and the third inter-layer insulation layer 35.

Subsequently, a first planarization layer 38 is formed and then, a color filter 39 is formed on an upper structure of the photodetector 31. Herein, a reference numeral 39A denotes an adjacent color filter.

Subsequently, a second planarization layer 40 is formed on the color filter 39.

Next, a microlens 41 of which a refraction index (n) is approximately 1,592 is formed on the color filter 39. Subsequently, a spin-on-glass (SOG) based oxide layer 42 of which a refraction index (n) is approximately 1.41, at a wavelength of approximately 450 nm is formed in order to cover the microlens 41. Herein, the oxide layer 42 is coated in a thickness ranging from approximately 4,000 Å to approximately 5,000 Å. Also, an insulation layer having a refraction index (n) less than approximately 1.5 can be used instead of the SOG based oxide layer.

Subsequently, a photoresist layer 43 is formed on the oxide layer 42.

Next, as shown in FIG. 3B, the photoresist layer 43 is selectively removed, thereby forming a photoresist pattern 43A.

Subsequently, as shown in FIG. 3C, the oxide layer 42 is selectively removed by using the photoresist pattern 43A as an etch mask. Herein, the photoresist pattern 43A uses a negative photoresist layer and the oxide layer 42 except a pixel is selectively removed by using a mask for opening the pixel portion.

Subsequently, as shown in FIG. 3D, the photoresist pattern 43A is removed.

Next, as shown in FIG. 3E, the low temperature insulating passivation layer 45 of which a refraction index (n) is approximately 1.55 at a wavelength of approximately 450 nm is formed on the oxide layer 42A. The low temperature insulating passivation layer 45 is formed in a thickness raging from approximately 2,000 Å to approximately 4,000 Å.

In case of the image sensor using 0.18 μm technology, as a height difference of an insulation layer formed on the photodetector 31 is reduced than before, an amount of the incident light increases, thereby improving the photosensitivity. However, there is a problem of generating a difference between the photosensitivity in edges and the photosensitivity in the center.

The above difference is caused by a phenomenon that the edges of the unit pixel are defocused. It is possible to generate this phenomenon if an incidence angle of the light is controlled. The CMOS image sensor according to the present invention controls a refraction angle of the light in order to collect the light incident on the photodetector much better.

The unit pixel of the CMOS image sensor in accordance with the present invention makes the light passing trough the low temperature insulating passivation layer incident on the microlens 41 through the SOG based oxide layer 42A.

The light passing through the microlens 41 is collected to the photodetector 31. At this time, a path to collect the light to the photodetector 41 is decided based on refraction indexes of the oxide layer 42A and the microlens 41.

An incidence angle determined by the light passing through two materials having different refraction indexes is decided on the Snell's Law, i.e., nᵢsin Θi=nᵣSin Θr. Herein, nᵢ denotes the refraction index of the oxide layer 42A and nᵣ denotes the refraction index of the microlens 41. Accordingly, the larger the difference between the refraction index of the microlens 41 and the refraction index of the oxide layer 42A is, the more the light is refracted. Thus, the light is collected to the photodetector 31 much better.

For the unit pixel included in the conventional CMOS image sensor, the insulating passivation layer 45 is formed directly on the microlens 41. However, since the difference between the refraction index of the low temperature insulating passivation layer 45 and the refraction index of the microlens 41 is not large, the refraction angle of the light becomes small. Thus, the light passing through the microlens 41 is not well collected to the photodetector. Particularly, in case of the light passing through the edges of the microlens 41, a degree that the light is collected to the photodetector is much worse.

However, the CMOS image sensor in accordance with the present invention forms the SOG based oxide layer 42 between the microlens 41 and the insulating passivation layer 45. Accordingly, when the light passing through the insulating passivation layer 45 passes the microlens 41, the light is transferred to the photodetector 31 by being more refracted to the photodetector 31 for the refraction index of the light. Particularly, the light passing through the edges of the microlens 41 in accordance with the present invention is refracted much more toward the photodetector compared with conventional image sensor, thereby improving a light collecting ability.

In the present invention, the SOG based oxide layer 42A is used as a layer capable of efficiently collecting the light since the refraction index of the SOG based oxide layer provides a big difference from the refraction index of the photoresist layer used as the microlens 41. Furthermore, any layers having a lower refraction index, i.e., n<1.5, than the refraction index of the microlens, i.e., n=1.592, can be used in the present invention.

Meanwhile, to try to make the refraction index of the oxide layer 42A less than the refraction index of the microlens 41, the refraction index of the oxide layer 42A gets larger than the refraction index of the insulating passivation layer 45.

Before being transferred to the microlens 41, the incident light passes through the insulating passivation layer 45 and the oxide layer 42A. At this time, when the light gets incident on the oxide layer 42 having a small refraction index from the insulating passivation layer 45 having a large refraction index, there is a possibility that the light is refracted to the opposite side of the photodetector 31. However, in this case, since the light gets incident vertically, i.e., in an angle of 90°, a phenomenon that the light is refracted in the opposite side of the photodetector is not happened.

Accordingly, in order not to produce the above problem, the present invention planarizes the oxide layer 42A surrounding the microlens and forms the insulating passivation layer 45 thereon.

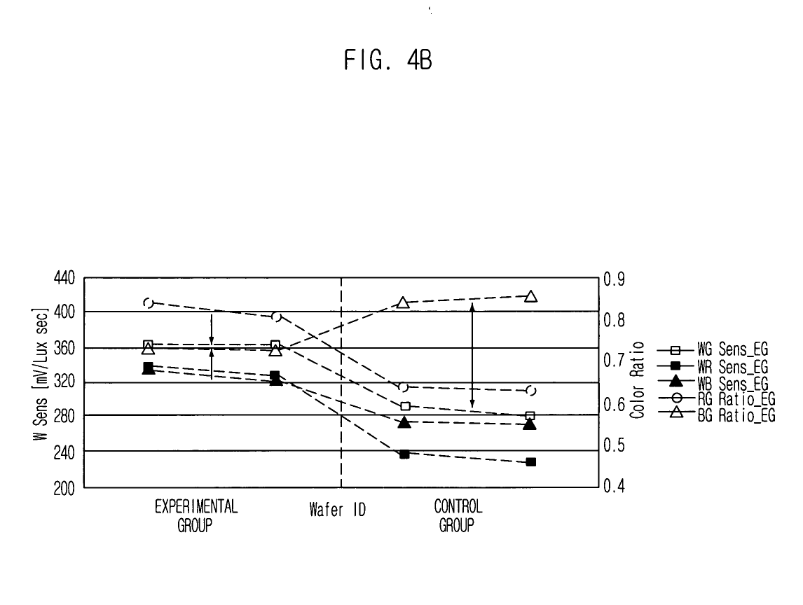

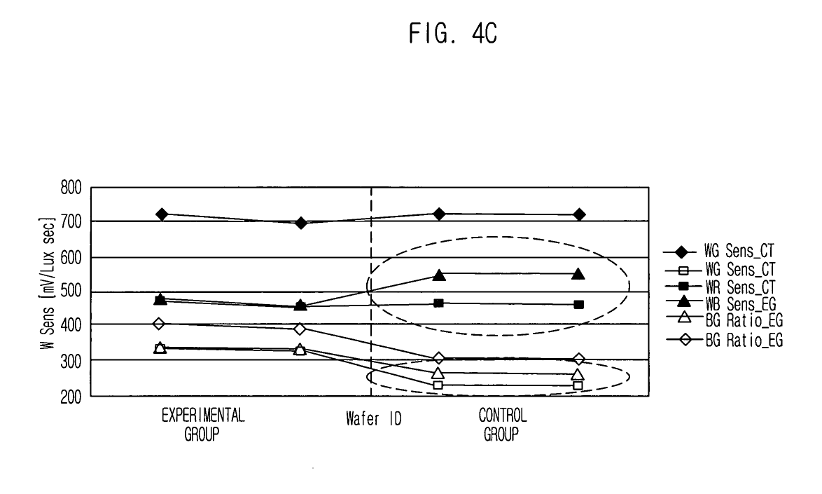

Table 1 shown below and FIGS. 4A to 4C illustrates an experiment data about photosensitivity of both a unit pixel of a CMOS image sensor fabricated as described in FIGS. 3A to 3E and a unit pixel of a conventional image sensor. Herein, photosensitivity is referred as a white sensitivity.

Table 1 illustrates that the data about photosensitivity used for the conventional image sensor and the image sensor in accordance with the present invention. Herein, the above data about photosensitivity illustrates each case of a red pixel, a blue pixel and a green pixel, respectively. More particularly, the above data indicates photosensitivity in edges and the center of a microlens. Furthermore, for each unit pixel, ratios of the red pixel and the blue pixel with respect to the green pixel are illustrated.

Referring to Table 1, a control group indicates a case that only low temperature insulating passivation layer is formed on a microlens in accordance with the conventional image sensor and a SOG deposition experimental group indicates a case that a SOG based oxide layer is formed between a microlens and an insulating passivation layer in accordance with the present invention. Hereinafter, the SOG deposition experimental group is expressed as an experimental group.

TABLE 1

| | | SOG Deposition | | | |
|---|---|---|---|---|---|
| | | Experimental Group | | | |
| | | SOG 5,000 Å + Low | | | |
| | | temperature | | Control Group | |
| | Scheme | insulating layer | | Low insulating layer | |
| | Condition | 2,000 Å | | 2,000 Å | |
| Test Item | Wafer ID | 18 | 19 | 20 | 21 |
| W-GREEN Sensitivity CENTER | mV/lux sec | 733 | 705 | 733 | 731 |
| W-RED Sensitivity CENTER | mV/lux sec | 477 | 457 | 468 | 464 |
| W-BLUE Sensitivity CENTER | mV/lux sec | 485 | 466 | 553 | 557 |
| W-GREEM TO GREEN _Ratio | — | 1.01 | 1.01 | 1.01 | 1.01 |
| CENTER | | | | | |
| W-RED TO GREEN _Ratio | — | 0.652 | 0.665 | 0.607 | 0.604 |
| CENTER | | | | | |
| W-BLUE TO GREEN _Ratio | — | 0.663 | 0.666 | 0.758 | 0.764 |
| CENTER | | | | | |
| W-GREEN_Sensitivity_EDGE | mV/lux sec | 412 | 398 | 314 | 308 |
| W-RED_Sensitivity_EDGE | mV/lux sec | 339 | 327 | 234 | 228 |
| W-BLUE_Sensitivity_EDGE | mV/lux sec | 336 | 324 | 273 | 270 |
| W-GREEN TO | — | 1 | 1 | 1 | 1 |
| GREEN_RATIO_EDGE | | | | | |
| W-RED TO GREEN_RATIO_EDGE | — | 0.823 | 0.822 | 0.745 | 0.740 |
| W-BLUE TO GREEN_RATIO_EDGE | — | 0.816 | 0.814 | 0.869 | 0.877 |

In the control group, a thickness of the low temperature insulating passivation layer is approximately 8,000 Å and in the experimental group, a thickness of the SOG based oxide layer is approximately 5,000 Å and a thickness of the low temperature insulating passivation layer is approximately 2,000 Å.

FIG. 4A illustrates a graph illustrating a data about photosensitivity in the center of a microlens for each red, blue and green unit pixel of a conventional CMOS image sensor and of a CMOS image sensor in accordance with the present invention. FIG. 4B is a graph illustrating a data about photosensitivity in edges of a microlens for each red, blue and green unit pixel of a conventional CMOS image sensor and of a CMOS image sensor in accordance with the present invention.

FIG. 4C is a graph illustrating the data shown in FIG. 4A and 4B at the same time.

First, if examining photosensitivity in the center of the microlens, there is almost no change in the photosensitivity difference between the control group and the experimental group in case of the green and red pixels. For instance, for the control group, the photosensitivity of the green pixel ranges from approximately 731 mV/lux sec to approximately 733 mV/lux sec and the photosensitivity of the red pixel ranges from approximately 464 mV/lux sec to approximately 468 mV/lux sec. For the experimental group, the photosensitivity of the green pixel ranges from approximately 705 mV/lux sec to approximately 733 mV/lux sec and the photosensitivity of the red pixel ranges from approximately 457 mV/lux sec to approximately 477 mV/lux sec.

Furthermore, in case of the blue pixel, the photosensitivity of the experimental group is decreased by approximately 60 mV/lux sec to approximately 80 mV/lux sec compared with the control group. For instance, for the control group, the photosensitivity of the blue pixel ranges from approximately 553 mV/lux sec to approximately 557 mV/lux sec. For the experimental group, the photosensitivity of the blue pixel ranges from approximately 466 mV/lux sec to approximately 485 mV/lux sec.

In case of the experimental group, the photosensitivity ratio of the blue pixel to the green pixel and the photosensitivity ratio of the,red pixel to the green pixel are shifted in almost the same values.

In general, in the CMOS image sensor, it is preferred that the photosensitivity ratio of the red pixel to the green pixel and the photosensitivity ratio of the green pixel to the blue pixel are almost the same. Thus, it is possible to obtain a good image quality produced by processed information when the red pixel and the blue pixel have almost the same photosensitivity.

In order to collect a light incident on the edges of the microlens to a photodetector, the CMOS image sensor in accordance with the present invention includes an oxide layer having a refraction index lower than the refraction index of the microlens. As a result, the photosensitivity ratio of the red pixel to the green pixel and the photosensitivity ratio of the blue pixel to the green pixel become almost the same, thereby improving the CMOS image sensor.

Meanwhile, if examining the photosensitivity in the edges of the microlens, in case of the green pixel and the red pixel, the photosensitivity of the control group increases by approximately 100 mV/lux sec compared with the photosensitivity of the experimental group. For instance, for the control group, the photosensitivity of the green pixel ranges from approximately 308 mV/lux sec to approximately 314 mV/lux sec and the photosensitivity of the red pixel ranges from approximately 228 mV/lux sec to approximately 234 mV/lux sec. For the experimental group, the photosensitivity of the green pixel ranges from approximately 398 mV/lux sec to approximately 412 mV/lux sec and the photosensitivity of the red pixel ranges from approximately 327 mV/lux sec to approximately 339 mV/lux sec.

Furthermore, in case of the blue pixel, the photosensitivity of the experimental group increases approximately 60 mV/lux sec compared with the photosensitivity of the control group. Accordingly, since the photosensitivity of the blue pixel increases less than the photosensitivity of the red pixel as much as approximately 40 mV/lux sec with respect to the red pixel of which the photosensitivity increases by approximately 100 mV/lux sec, the photosensitivity of the blue pixel is shifted in a relatively similar level with the photosensitivity of the red pixel.

Thus, in case of the experimental group, the photosensitivity ratio of the blue pixel to the green pixel and the photosensitivity ratio of the red pixel to the green pixel are shifted in almost the same value.

In summary, by forming the SOG based oxide layer 42A between the microlens 41 and the insulating passivation layer 45 for the CMOS image sensor in accordance with the present invention, the photosensitivity in the edges of the microlens is greatly increased without changing the photosensitivity of the center of the microlens. The CMOS image sensor in accordance with the present invention provides effects of increasing the photosensitivity of the red pixel and the photosensitivity of the blue pixel as much as approximately 100 mV/lux sec and increasing the photosensitivity of the blue pixel as much as approximately 60 mV/lux sec.

Furthermore, the CMOS image sensor fabricated by forming the SOG based oxide layer between the microlens 41 and the insulating passivation layer 45 serves a role in shifting the photosensitivity of the blue pixel to make the photosensitivity of the blue pixel approach to the photosensitivity ratio of the blue pixel to the green pixel and of the red pixel to the green pixel.

Furthermore, since a characteristic of a dead zone is lowered from approximately −4 mV to approximately −2.8 mV, a defect caused by black fine dots appearing on an image can be reduced below the half level of the defect.

The present invention makes a light to be collected to a photodetector at the maximum extent, thereby improving photosensitivity of a unit pixel.

Furthermore, a CMOS image sensor in accordance with the present invention reduces a difference between photosensitivity in the center of a unit pixel and photosensitivity in edges of a unit pixel and thus, a more reliable image processing with respect to a light is possible through the CMOS image sensor in accordance with the present invention.

The present application contains subject matter related to the Korean patent application No. KR 2004-0072280, filed in the Korean Patent Office on Sep. 9, 2004 the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

1. A complementary metal oxide semiconductor (CMOS) image sensor, comprising:
a photodetector;
a microlens formed on the photodetector;
an insulating passivation layer formed on the microlens to protect the microlens; and
an oxide layer with a refraction index lower than that of the microlens formed between the microlens and the insulating passivation layer.

2. The CMOS image sensor of claim 1, wherein the oxide layer covering the microlens is formed by a planarized layer.

3. The CMOS image sensor of claim 1, wherein the oxide layer is made of a spin-on-glass layer.

4. The CMOS image sensor of claim 3, wherein the oxide layer is formed in a thickness ranging from approximately 4,000 Å to approximately 5,000 Å.

5. The CMOS image sensor of claim 1, wherein a thickness of the insulating passivation layer ranges from approximately 2,000 Å to approximately 4,000 Å.

6. The CMOS image sensor of claim 3, wherein a refraction index of the oxide layer is approximately 1.41.

7. The CMOS image sensor of claim 1, wherein a refraction index of the microlens is approximately 1.592.

8. The CMOS image sensor of claim 1, wherein a refraction index of the insulating passivation layer is approximately 1.55.

9. The CMOS image sensor of claim 1, wherein further including a color filter layer between the photodetector ad the microlens.

10. The CMOS image sensor of claim 9, wherein further including a plurality of interconnection lines between the photodetector and the color filter and a plurality of inter-layer insulation layers of the plurality of interconnection lines.

11. A method for fabricating a CMOS image sensor, comprising the steps of:
forming a photodetector on a substrate;
forming a microlens on the photodetector;
forming an oxide layer having a refraction index lower than the microlens on the microlens; and
forming an insulating passivation layer for protecting the microlens on the oxide layer.

12. The method of claim 11, wherein further including the step of planarizing the oxide layer formed on the microlens.

13. The method of claim 11, wherein the oxide layer is made of a spin-on-glass (SOG) layer.

14. The method of claim 13, wherein the oxide layer is formed in a thickness ranging from approximately 4,000 Å to approximately 5,000 Å.

15. The method of claim 11, wherein the insulating passivation layer is formed in a thickness ranging from approximately 2,000 Å to approximately 4,000 Å.

16. The method of claim 13, wherein a refraction index of the oxide layer is approximately 1.41.

17. The method of claim 11, wherein a refraction index of the microlens is approximately 1.592.

18. The method of claim 11, wherein a refraction index of the insulating passivation layer is approximately 1.55.

19. The method of claim 11, wherein further including a step of forming a color filter layer between the photodetector and the microlens.

20. The method of claim 19, wherein further including the step of forming a plurality of interconnection lines between the photodetector and the color filter and a plurality of inter-layer insulation layers for insulating the plurality of interconnection lines.
